(19) United States
(12) Patent Application Publication
(10) Pub. No.: US 2026/0182012 A1
(43) Pub. Date: Jun. 25, 2026

(54) SEMICONDUCTOR DEVICE

(71) Applicant: Renesas Electronics Corporation, Tokyo (JP)

(72) Inventors: Takahiro MORI, Tokyo (JP); Komaki INOUE, Tokyo (JP)

(21) Appl. No.: 19/368,484

(22) Filed: Oct. 24, 2025

(30) Foreign Application Priority Data
Dec. 23, 2024 (JP) 2024-226358

(51) Int. Cl. H10D 84/83; H10D 62/13; H10D 62/60; H10D 84/01

(52) U.S. Cl. CPC H10D 84/835; H10D 62/155; H10D 62/60; H10D 84/83125; H10D 84/0133

(57) ABSTRACT

A semiconductor device includes one or more LDMOS transistors and a semiconductor substrate having an upper surface. Each of the one or more LDMOS transistors includes: a plurality of impurity diffusion layers formed in the semiconductor substrate at the upper surface; a plurality of drain layers formed in the semiconductor substrate at the upper surface; and a plurality of insulating films formed on the upper surface. Each of the plurality of impurity diffusion layers, each of the plurality of drain layers, and each of the plurality of insulating films extend along a first direction in plan view. The plurality of impurity diffusion layers are arranged along a second direction perpendicular to the first direction in plan view while interposing a gap between two adjacent impurity diffusion layers among the plurality of impurity diffusion layers.

### CROSS-REFERENCE TO RELATED APPLICATION

The disclosure of Japanese Patent Application No. 2024-226358 filed on Dec. 23, 2024, including the specification, drawings and abstract is incorporated herein by reference in its entirety.

### BACKGROUND

The present disclosure relates to a semiconductor device.

There is disclosed techniques listed below.

[Patent Document 1] Japanese Unexamined Patent Application Publication No. 2017-45884

A semiconductor device disclosed in the Patent Document 1 includes a semiconductor substrate and a laterally diffused metal oxide semiconductor (LDMOS) transistor.

The semiconductor substrate has an upper surface. The semiconductor substrate includes a first impurity diffusion layer, a second impurity diffusion layer, a drain layer, a first body layer, a second body layer, and a drift layer. The first impurity diffusion layer and the second impurity diffusion layer are formed in the semiconductor substrate at the upper surface of the semiconductor substrate. The first impurity diffusion layer and the second impurity diffusion layer extend along a first direction in plan view. The first impurity diffusion layer and the second impurity diffusion layer are arranged along a second direction perpendicular to the first direction in plan view while interposing a gap between the first impurity diffusion layer and the second impurity diffusion layer. The drift layer is formed in the semiconductor substrate at the upper surface of the semiconductor substrate. The drift layer extends along the first direction, and is positioned between the first impurity diffusion layer and the second impurity diffusion layer.

The first body layer is formed in the semiconductor substrate and on the upper surface of the semiconductor substrate to surround the first impurity diffusion layer in cross-sectional view. The second body layer is formed in the semiconductor substrate and on the upper surface of the semiconductor substrate to surround the second impurity diffusion layer in cross-sectional view. The drift layer is formed in the semiconductor substrate and on the upper surface of the semiconductor substrate to surround the drain layer in cross-sectional view. Each of the first impurity diffusion layer and the second impurity diffusion layer includes a source layer and a backgate layer.

The LDMOS transistor includes the first impurity diffusion layer, the second impurity diffusion layer, the first body layer, the second body layer, the drain layer, and the drift layer. The LDMOS transistor further includes a first insulating film, a second insulating film, a first gate insulating film, a second gate insulating film, a first gate electrode, and a second gate electrode.

The first insulating film is formed on the upper surface of the semiconductor substrate to be in contact with the drift layer and to separate from the first impurity diffusion layer. The second insulating film is formed on the upper surface of the semiconductor substrate to be in contact with the drift layer and to separate from the second impurity diffusion layer. The first gate insulating film is formed on the upper surface of the semiconductor substrate between the first insulating film and the first impurity diffusion layer. The second gate insulating film is formed on the upper surface of the semiconductor substrate between the second insulating film and the second impurity diffusion layer. The first gate electrode is formed on the first gate insulating film and on the first insulating film, and the second gate electrode is formed on the second gate insulating film and on the second insulating film.

### SUMMARY

In the LDMOS transistor of the semiconductor device disclosed in the Patent Document 1, when the number of fingers increases or when the number of drain layers increases, the electric properties of the LDMOS transistor are difficult to linearly change relative to the number of fingers. Other objective and novel characteristics will become apparent from the description of the present specification and the accompanying drawings.

A semiconductor device according to the present disclosure includes one or more LDMOS transistors and a semiconductor substrate having an upper surface. Each of the one or more LDMOS transistors includes: a plurality of impurity diffusion layers formed in the semiconductor substrate at the upper surface; a plurality of drain layers formed in the semiconductor substrate at the upper surface; and a plurality of insulating films formed on the upper surface. Each of the plurality of impurity diffusion layers, each of the plurality of drain layers, and each of the plurality of insulating films extend along a first direction in plan view. The plurality of impurity diffusion layers are arranged along a second direction perpendicular to the first direction in plan view while interposing a gap between adjacent two impurity diffusion layers among the plurality of impurity diffusion layers. The plurality of impurity diffusion layers include a first impurity diffusion layer and a second impurity diffusion layer which are positioned on both ends in the second direction, and a third impurity diffusion layer positioned between the first impurity diffusion layer and the second impurity diffusion layer. Each of the plurality of drain layers is positioned between two adjacent impurity diffusion layers among the plurality of impurity diffusion layers. Each of the plurality of insulating films is positioned between one of the plurality of drain layers and one of the plurality of impurity diffusion layers which are adjacent to each other, to be in contact with one of the plurality of drain layers and to separate from one of the plurality of impurity diffusion layers. In a first LDMOS transistor among the one or more LDMOS transistors, each of the first impurity diffusion layer and the second impurity diffusion layer includes a first backgate layer but does not include a source layer. The third impurity diffusion layer in the first LDMOS transistor includes a second backgate layer and a first source layer which are alternately arranged along the first direction.

According to a semiconductor device according to the present disclosure, electric properties of an LDMOS transistor can be linearly changed relative to the number of fingers.

### BRIEF DESCRIPTIONS OF THE DRAWINGS

FIG. 1 is a plan view illustrating a semiconductor device DEV1 on an LDMOS transistor Tr1.

FIG. 2 is a cross-sectional view illustrating the semiconductor device DEV1 taken along the line II-II of FIG. 1.

FIG. 3 is a cross-sectional view illustrating the semiconductor device DEV1 taken along the line III-III of FIG. 1.

FIG. 4 is a plan view illustrating the semiconductor device DEV1 on an LDMOS transistor Tr2.

FIG. 5 is a cross-sectional view illustrating the semiconductor device DEV1 taken along the line V-V of FIG. 4.

FIG. 6 is a cross-sectional view illustrating the semiconductor device DEV1 taken along the line VI-VI of FIG. 4.

FIG. 7 is a plan view illustrating the semiconductor device DEV1 on an LDMOS transistor Tr3.

FIG. 8 is a cross-sectional view illustrating the semiconductor device DEV1 taken along the line VIII-VIII of FIG. 7.

FIG. 9 is a cross-sectional view illustrating the semiconductor device DEV1 taken along the line IX-IX of FIG. 7.

FIG. 10 is a circuit diagram illustrating a current mirror circuit.

FIG. 11 is a manufacturing process diagram of the semiconductor device DEV1.

FIG. 12 is a cross-sectional view for explaining an ion implanting step S1.

FIG. 13 is a cross-sectional view for explaining an insulating-film forming step S2.

FIG. 14 is a cross-sectional view for explaining a gate-insulating-film forming step S3.

FIG. 15 is a cross-sectional view for explaining a gate-electrode depositing step S4.

FIG. 16 is a cross-sectional view for explaining a gate-electrode etching step S5.

FIG. 17 is a cross-sectional view for explaining an ion implanting step S6.

FIG. 18 is a cross-sectional view for explaining a sidewall-spacer forming step S7.

FIG. 19 is a cross-sectional view for explaining an ion implanting step S8.

FIG. 20 is a cross-sectional view for explaining an ion implanting step S9.

FIG. 21 is a cross-sectional view for explaining an interlayer-insulating-film forming step S10.

FIG. 22 is a cross-sectional view for explaining a contact-plug forming step S11.

FIG. 23 is a plan view illustrating a semiconductor device DEV4 on an LDMOS transistor Tr4.

FIG. 24 is a cross-sectional view illustrating the semiconductor device DEV4 taken along the line XXIV-XXIV of FIG. 23.

FIG. 25 is a cross-sectional view illustrating the semiconductor device DEV4 taken along the line XXV-XXV of FIG. 23.

FIG. 26 is a cross-sectional view illustrating a semiconductor device DEV2.

FIG. 27 is a manufacturing process diagram of the semiconductor device DEV2.

FIG. 28 is a cross-sectional view for explaining an ion implanting step S1 in a method of manufacturing the semiconductor device DEV2.

FIG. 29 is a cross-sectional view for explaining a gate-electrode etching step S5 in the method of manufacturing the semiconductor device DEV2.

FIG. 30 is a cross-sectional view for explaining an ion implanting step S13 in the method of manufacturing the semiconductor device DEV2.

FIG. 31 is a cross-sectional view illustrating a semiconductor device DEV3.

FIG. 32 is a cross-sectional view for explaining an ion implanting step S1 in a method of manufacturing the semiconductor device DEV3.

FIG. 33 is a cross-sectional view for explaining a gate-electrode etching step S5 in the method of manufacturing the semiconductor device DEV3.

FIG. 34 is a cross-sectional view for explaining an ion implanting step S13 in the method of manufacturing the semiconductor device DEV3.

### DETAILED DESCRIPTION

Details of embodiments of the present disclosure will be described with reference to the drawings. The same or similar components are denoted with the same reference symbol throughout the following drawings, and repetitive description thereof will be omitted.

### First Embodiment

A semiconductor device DEV1 according to a first embodiment will be described.

### Configuration of Semiconductor Device DEV1

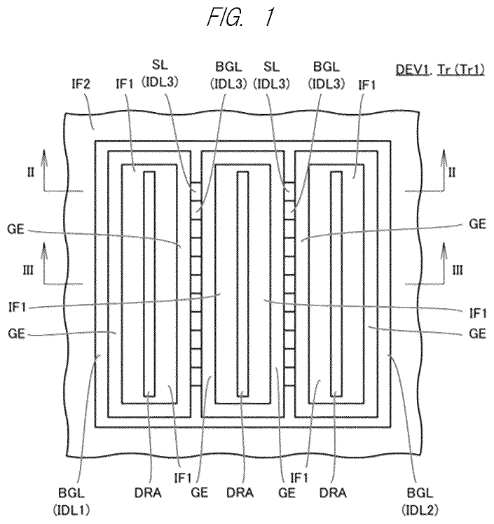

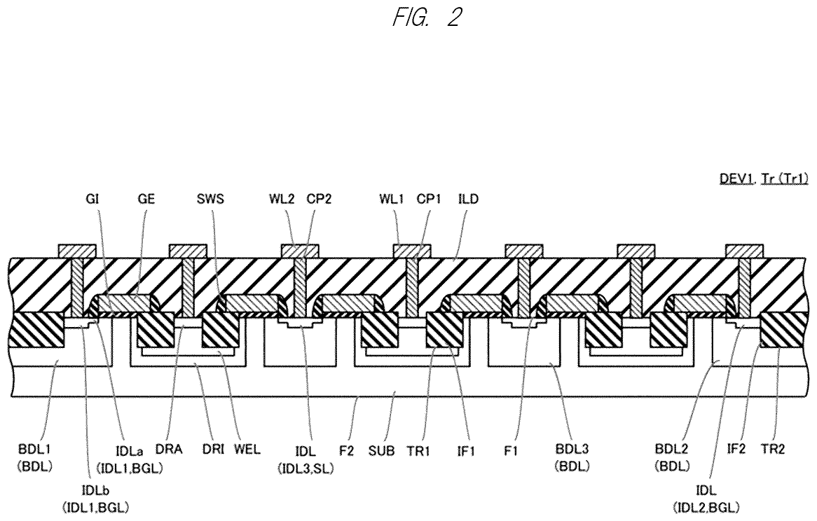

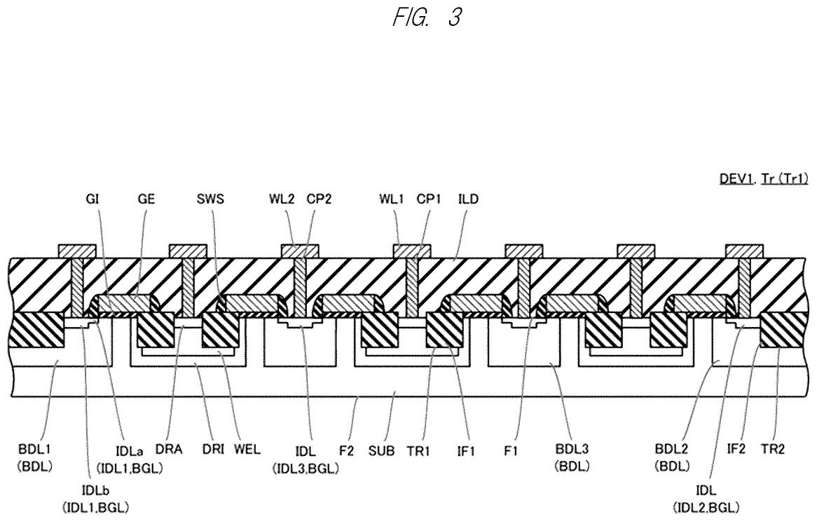

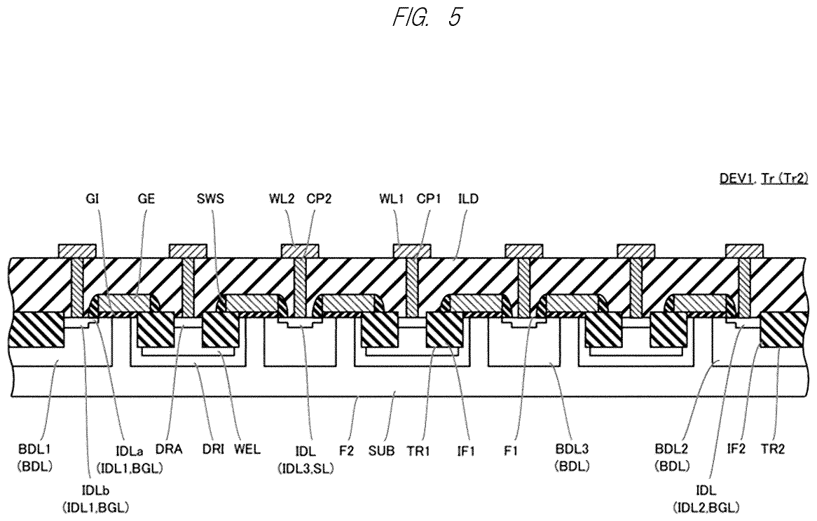

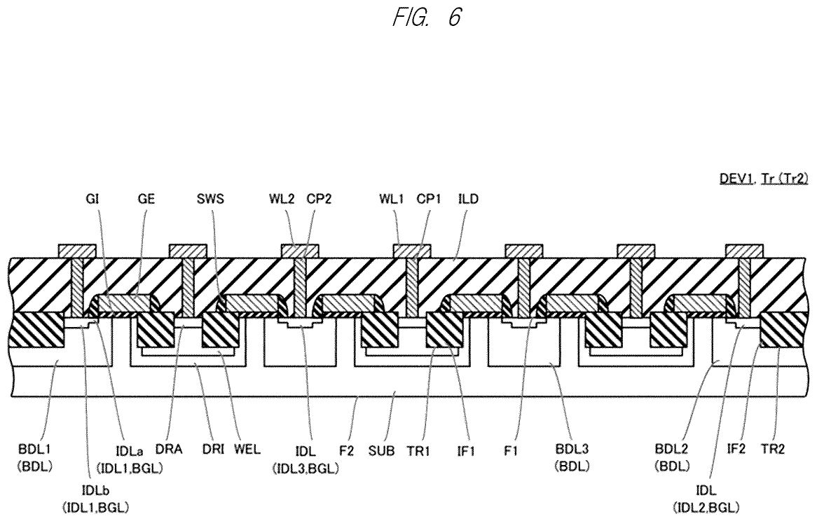

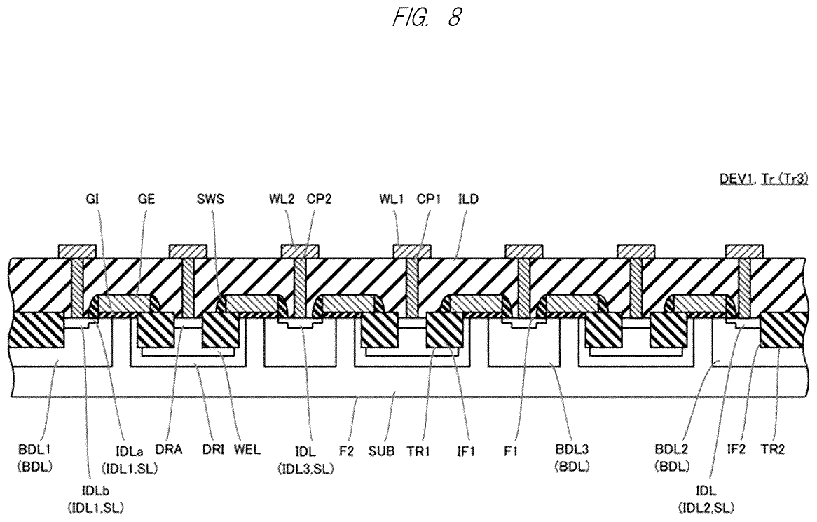

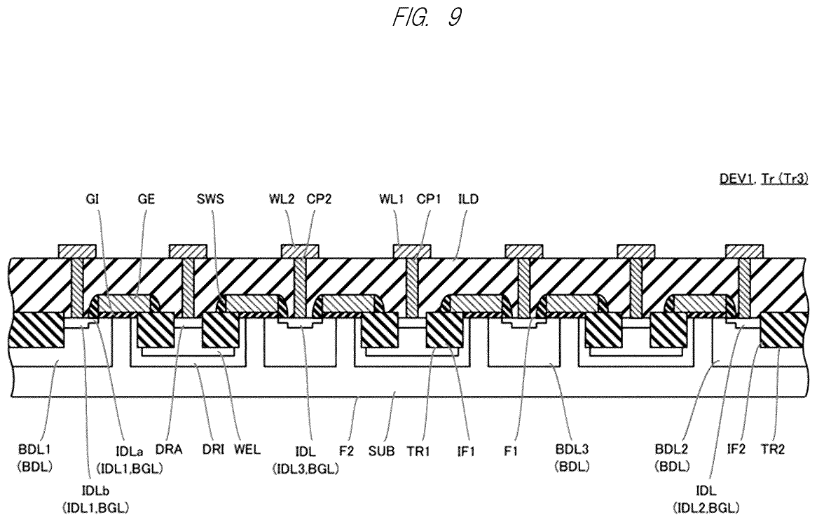

The semiconductor device DEV1 includes a plurality of LDMOS transistors Tr as illustrated in FIGS. 1 to 9. The number of the LDMOS transistors included in the semiconductor device DEV1 may be one. The semiconductor device DEV1 includes a semiconductor substrate SUB. The semiconductor substrate SUB has an upper surface F1 and a lower surface F2 opposite to the upper surface F1. The semiconductor substrate SUB includes a plurality of impurity diffusion layers IDL, a plurality of drain layers DRA, a plurality of body layers BDL, and a plurality of drift layers DRI.

The plurality of impurity diffusion layers IDL and the plurality of drain layers DRA are formed in the semiconductor substrate SUB at the upper surface F1. The impurity diffusion layer IDL and the drain layer DRA extend along a first direction DR1 in plan view. The plurality of impurity diffusion layers IDL are arranged along a second direction DR2 perpendicular to the first direction DR1 in plan view to interpose a gap between two adjacent impurity diffusion layers among the plurality of impurity diffusion layers IDL. The drain layer DRA is positioned between two adjacent impurity diffusion layers among the plurality of impurity diffusion layers IDL.

The impurity diffusion layer IDL includes a first part IDLa and a second part IDLb. The first part ILDa is positioned between the second part IDLb and the drain layer DRA. That is, the impurity diffusion layer IDL has a lightly doped diffusion (LDD) structure.

The body layer BDL is formed on the upper surface F1 to surround the impurity diffusion layer IDL in cross-sectional view. The drift layer DRI is formed on the upper surface F1 to surround the drain layer DRA in cross-sectional view. The semiconductor substrate SUB may further include a plurality of well layers WEL. The well layer WEL is formed to surround the drain layer DRA and to be surrounded by the drift layer DRI in cross-sectional view.

The semiconductor substrate SUB is made of, for example, single crystal silicon. A conductive type of the semiconductor substrate SUB is a first conductive type. A conductive type of the body layer BDL is the first conductive type. Each conductive type of the drain layer DRA, the well layer WEL, and the drift layer DRI is a second conductive type opposite to the first conductive type. The first conductive type is, for example, p-type, and the second conductive type is, for example, n-type. The first conductive type may be n-type, and the second conductive type may be p-type.

The semiconductor device DEV1 further includes a plurality of insulating films IF1. The insulating film IF1 is formed on the upper surface F1. The insulating films IF1 extend along the first direction DR1. A plurality of trenches TR1 are formed on the upper surface F1. The trenches TR1 extend toward the lower surface F2. The trench TR1 is positioned between the impurity diffusion layer IDL and the drain layer DRA which are adjacent to each other. The trench TR1 is in contact with the drain layer DRA, and separates from the impurity diffusion layer IDL. The insulating film IF1 is formed in the trench TR1. Thus, the insulating film IF1 is formed on the upper surface F1 to be in contact with the drain layer DRA and to separate from the impurity diffusion layer IDL. The insulating film IF1 is made of, for example, silicon oxide.

The semiconductor device DEV1 further includes a plurality of gate insulating films GI and a plurality of gate electrodes GE. The gate insulating film GI is formed on the upper surface F1 positioned between the insulating film IF1 and the impurity diffusion layer IDL which are adjacent to each other. The gate insulating film GI is made of, for example, silicon oxide. The gate electrode GE is formed on the gate insulating film GI and the insulating film IF1 which are adjacent to each other. The gate electrode GE is made of, for example, polysilicon.

The LDMOS transistor Tr includes the plurality of impurity diffusion layers IDL, the plurality of drain layers DRA, the plurality of body layers BDL, the plurality of drift layers DRI, the plurality of insulating films IF1, the plurality of gate insulating films GI, and the plurality of gate electrodes GE. The semiconductor device DEV1 further includes an insulating film IF2. The insulating film IF2 is formed on the upper surface F1 to surround the LDMOS transistor Tr in plan view. The trench TR2 extending toward the lower surface F2 is formed in the upper surface F1, and the insulating film IF2 is formed in the trench TR2. The LDMOS transistor Tr is electrically isolated from other element by the insulating film IF2. The insulating film IF2 is made of, for example, silicon oxide.

The semiconductor device DEV1 further includes a sidewall spacer SWS. The sidewall spacer SWS is formed on the upper surface F1 (on the first part IDLa) and on the insulating film IF1 to be in contact with both sides of the gate electrode GE. The sidewall spacer SWS is made of, for example, silicon nitride.

The semiconductor device DEV1 further includes an interlayer insulating film ILD. The interlayer insulating film ILD is formed on the upper surface F1 to cover the insulating film IF1, the insulating film IF2, the gate electrode GE, and the sidewall spacer SWS. The interlayer insulating film ILD is made of, for example, silicon oxide.

The semiconductor device DEV1 further includes a wiring WL1, a wiring WL2, a contact plug CP1, and a contact plug CP2. The wiring WL1 and the wiring WL2 are formed on the interlayer insulating film ILD. Each of the wiring WL1 and the wiring WL2 is made of, for example, aluminum or an aluminum alloy. The contact plug CP1 and the contact plug CP2 are formed in the interlayer insulating film ILD. The contact plug CP1 electrically connects the wiring WL1 and a drain layer DRA. The contact plug CP2 electrically connects the wiring WL2 and the impurity diffusion layer IDL. Each of the contact plug CP1 and the contact plug CP2 is made of, for example, tungsten.

As illustrated in FIGS. 1 to 3, in the LDMOS transistor Tr1 among the plurality of LDMOS transistors Tr, each of the impurity diffusion layer IDL1 and the impurity diffusion layer IDL2, which are positioned on both ends in the second direction DR2 among the plurality of impurity diffusion layers IDL, includes only a backgate layer BGL. That is, each of the impurity diffusion layer IDL1 and the impurity diffusion layer IDL2 includes the backgate layer BGL, but does not include any source layer. A conductive type of the backgate layer BGL is the first conductive type. In the LDMOS transistor Tr1, the impurity diffusion layer IDL3 positioned between the impurity diffusion layer IDL1 and the impurity diffusion layer IDL2 among the plurality of impurity diffusion layers IDL includes the backgate layer BGL and the source layer SL which are alternately arranged along the first direction DR1. A conductive type of the source layer SL is the second conductive type.

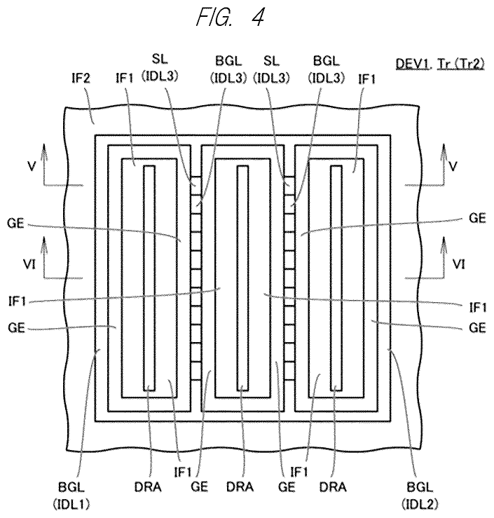

As illustrated in FIGS. 4 to 6, in the LDMOS transistor Tr2 among the plurality of LDMOS transistors Tr, each of the impurity diffusion layer IDL1 and the impurity diffusion layer IDL2 includes only the backgate layer BGL. That is, each of the impurity diffusion layer IDL1 and the impurity diffusion layer IDL2 includes the backgate layer BGL, but does not include any source layer. In the LDMOS transistor Tr2, the impurity diffusion layer IDL3 includes the backgate layer BGL and the source layer SL which are alternately arranged along the first direction DR1. Note that the number of the plurality of drain layers DRA in the LDMOS transistor Tr2 may be different from the number of the plurality of drain layers DRA in the LDMOS transistor Tr1.

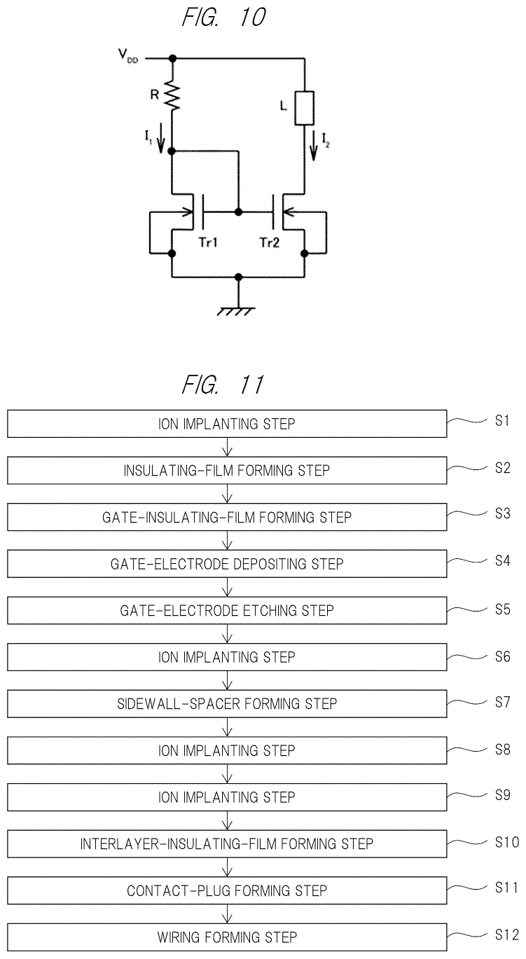

As illustrated in FIG. 10, the semiconductor device DEV1 includes a current mirror circuit. The current mirror circuit includes the LDMOS transistor Tr1, the LDMOS transistor Tr2, a resistor R, and a load L. The drain layer DRA of the LDMOS transistor Tr1 and the drain layer DRA of the LDMOS transistor Tr2 are electrically connected to a drain voltage V_{DD}. The source layer SL of the LDMOS transistor Tr1 and the source layer SL of the LDMOS transistor Tr2 are grounded. That is, the LDMOS transistor Tr1 and the LDMOS transistor Tr2 are connected in parallel.

The gate electrode GE of the LDMOS transistor Tr1 is electrically connected to the gate electrode GE of the LDMOS transistor Tr2. The gate electrode GE of the LDMOS transistor Tr1 and the gate electrode GE of the LDMOS transistor Tr2 are electrically connected to the drain layer DRA of the LDMOS transistor Tr1. The resistor R is electrically connected between the drain layer DRA of the LDMOS transistor Tr1 and the drain voltage V_{DD}. The load L is electrically connected between the drain layer DRA of the LDMOS transistor Tr2 and the drain voltage V_{DD}.

In the current mirror circuit, the ratio between current I₁ flowing in the LDMOS transistor Tr1 and current I₂ flowing in the LDMOS transistor Tr2 is determined by a mirror ratio, that is, a ratio between a size of the LDMOS transistor Tr1 and a size of the LDMOS transistor Tr2. For example, when the gate length of the LDMOS transistor Tr1 is equal to the gate length of the LDMOS transistor Tr2 while the gate width of the LDMOS transistor Tr1 is equal to the gate width of the LDMOS transistor Tr2, the mirror ratio is 1:1, and the current I₂ is equal to the current I₁. When the gate length of the LDMOS transistor Tr1 is equal to the gate length of the LDMOS transistor Tr2 while the gate width of the LDMOS transistor Tr2 is twice the gate width of the LDMOS transistor Tr1, the mirror ratio is 1:2, and the current I₂ is twice the current I₁. Note that the gate width in the LDMOS transistor Tr1 and the LDMOS transistor Tr2 is proportional to the number of fingers.

In the LDMOS transistor Tr1 and the LDMOS transistor Tr2, the number of the plurality of drain layers DRA is, for example, equal to or smaller than six. In an assumption that the number of the plurality of drain layers DRA is “n” (“n” is a natural number), each of the number of fingers of the LDMOS transistor Tr1 and the number of fingers of the LDMOS transistor Tr2 is expressed as “2n−2”.

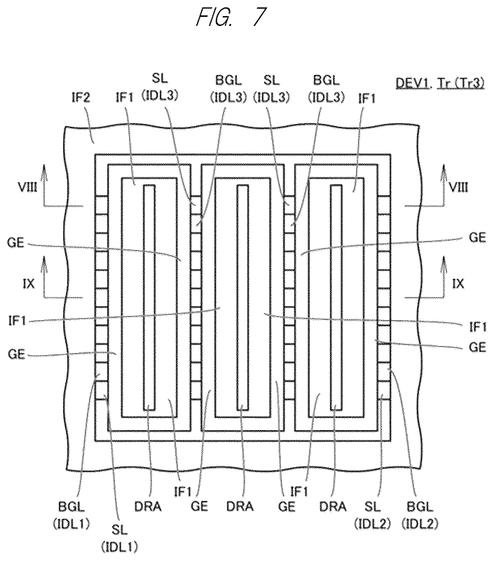

As illustrated in FIGS. 7 to 9, the plurality of LDMOS transistors Tr may include an LDMOS transistor Tr3. In the LDMOS transistor Tr3, each of the impurity diffusion layer IDL1, the impurity diffusion layer IDL2, and the impurity diffusion layer IDL3 includes the backgate layer BGL and the source layer SL which are alternately arranged along the first direction DR1.

### Method of Manufacturing Semiconductor Device DEV1

As illustrated in FIG. 11, a method of manufacturing the semiconductor device DEV1 includes an ion implanting step S1, an insulating-film forming step S2, a gate-insulating-film forming step S3, a gate-electrode depositing step S4, a gate-electrode etching step S5, an ion implanting step S6, a sidewall-spacer forming step S7, an ion implanting step S8, and an ion implanting step S9. The method of manufacturing the semiconductor device DEV1 further includes an interlayer-insulating-film forming step S10, a contact-plug forming step S11, and a wiring forming step S12.

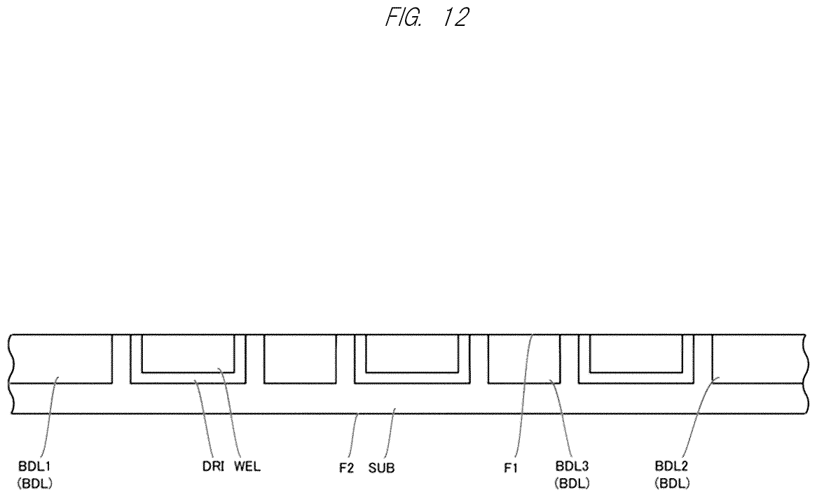

As illustrated in FIG. 12, in the ion implanting step S1, ion implantation is performing by using a resist pattern formed on the upper surface F1 as a mask, thereby forming the body layer BDL, the well layer WEL, and the drift layer DRI.

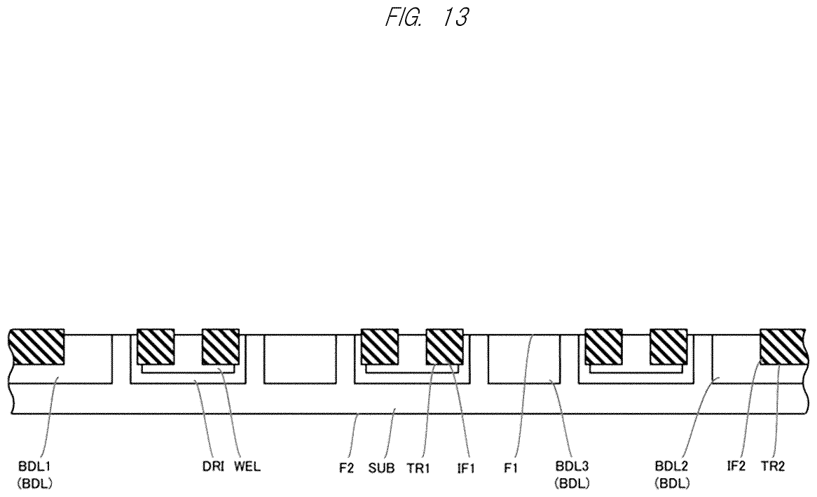

As illustrated in FIG. 13, in the insulating-film forming step S2, the insulating films IF1 and the insulating film IF2 are formed. In the insulating-film forming step S2, firstly, a hard mask is formed on the upper surface F1. Secondly, the semiconductor substrate SUB is subjected to dry etching through openings of the hard mask, thereby forming the trench TR1 and the trench TR2 in the upper surface F1. Thirdly, a constituent material of the insulating film IF1 or the like is deposited in the trench TR1 and the trench TR2 and on the hard mask by, for example, a chemical vapor deposition (CVD) method. Fourthly, a constituent material of the insulating film IF1 or the like, which is formed outside the trench TR1 and the trench TR2, is removed by, for example, a CMP method or etching-back.

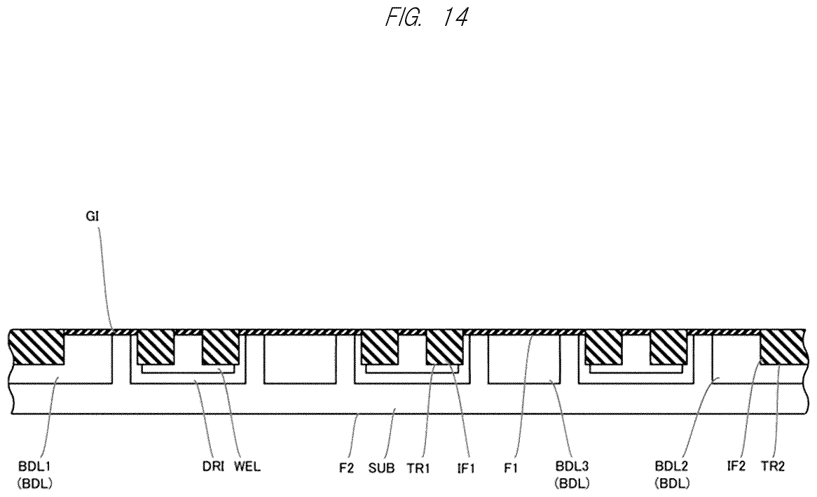

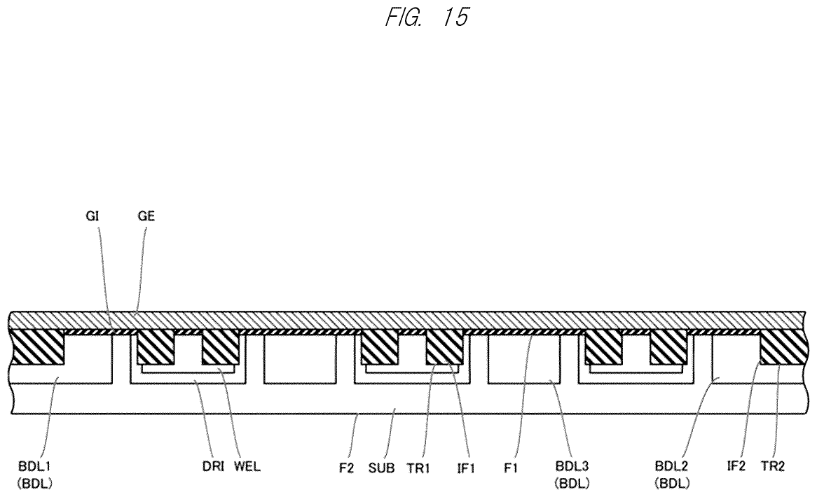

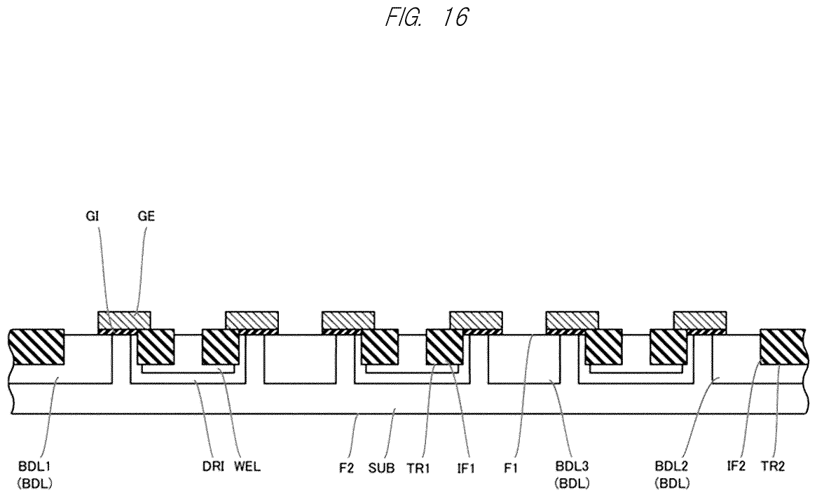

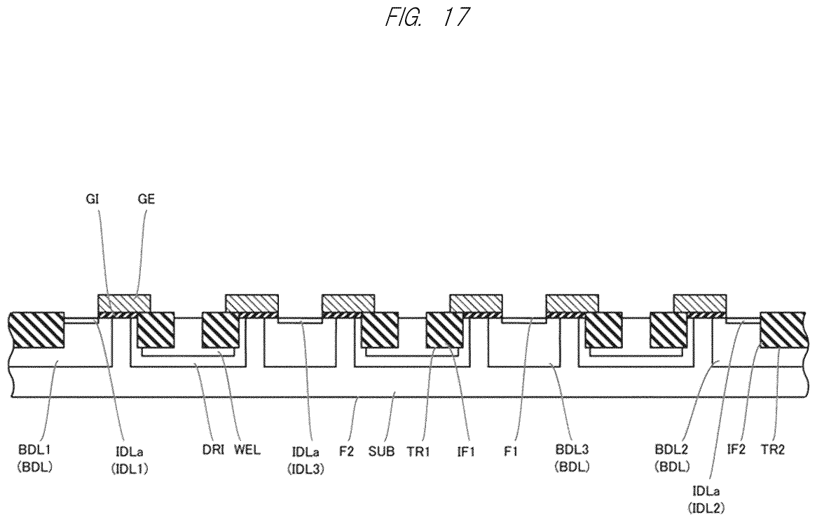

As illustrated in FIG. 14, in the gate-insulating-film forming step S3, for example, the upper surface F1 is thermally oxidized, thereby forming the gate insulating film GI on the upper surface F1. As illustrated in FIG. 15, in the gate-electrode depositing step S4, the gate electrode GE is formed on the gate insulating film GI by, for example, a CVD method. As illustrated in FIG. 16, in the gate-electrode etching step S5, the gate electrode GE is dry-etched through openings of the resist pattern formed on the gate electrode GE, thereby patterning the gate electrode GE. At this time, the gate insulating film GI positioned in other region than a region below the patterned gate electrode GE is also removed.

As illustrated in FIG. 17, in the ion implanting step S6, ion implantation is performed by using the gate electrode GE, the insulating film IF1, and the insulating film IF2 as a mask, thereby forming the first part IDLa.

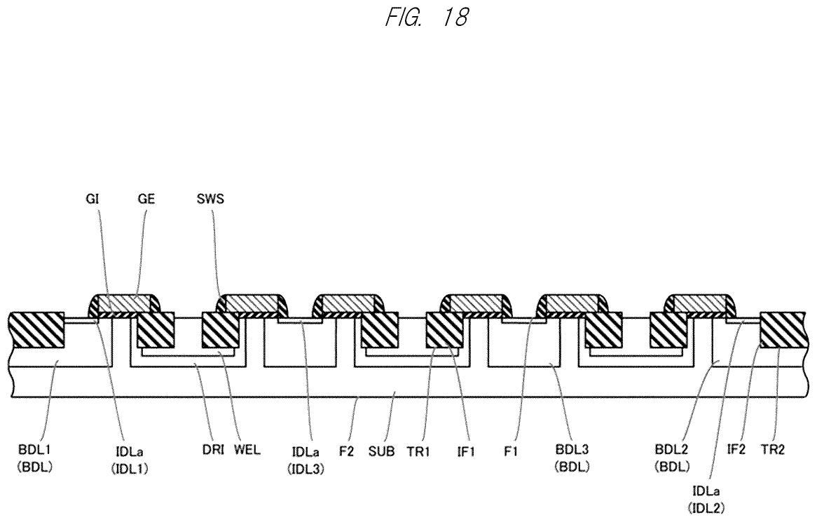

As illustrated in FIG. 18, in the sidewall-spacer forming step S7, the sidewall spacer SWS is formed on the upper surface F1 (the first part IDLa) and on the insulating film IF1 to be in contact with both side surfaces of the gate electrode GE. In the sidewall-spacer forming step S7, firstly, a constituent material of the sidewall spacer SWS is deposited on the upper surface F1 by, for example, a CVD method to cover the insulating film IF1, the insulating film IF2, the gate electrode GE, and the gate insulating film GI. Secondly, the constituent material of the sidewall spacer SWS is etched back.

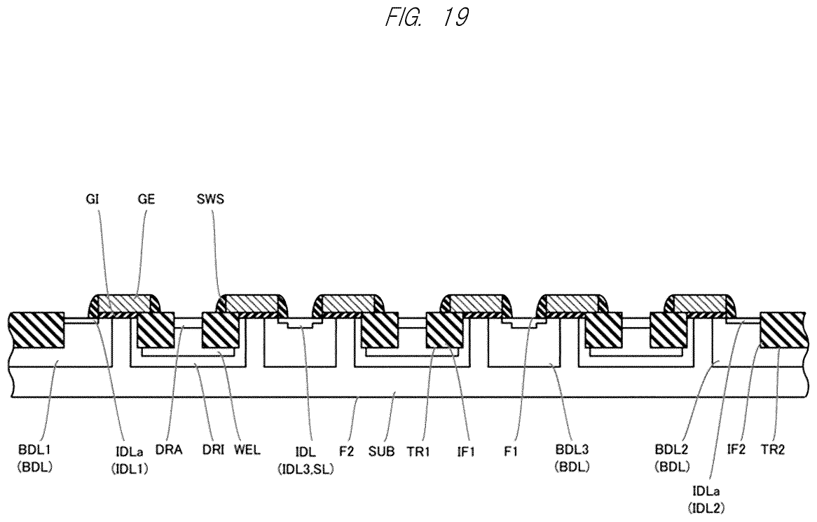

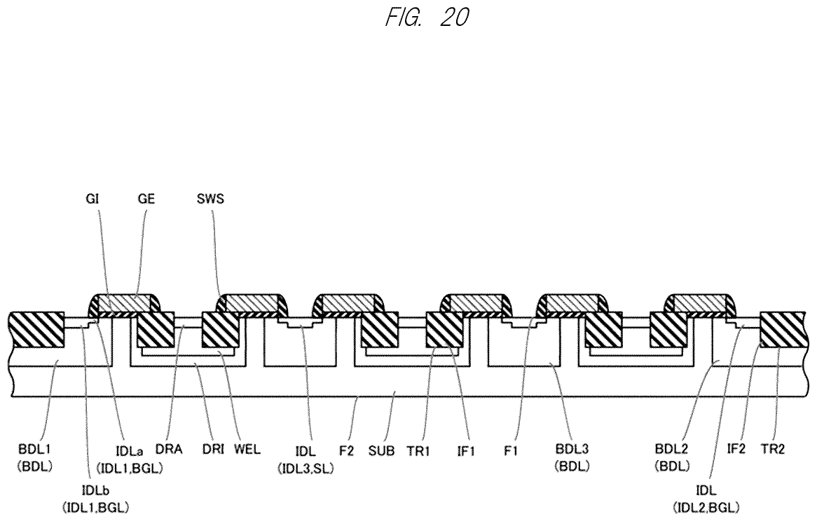

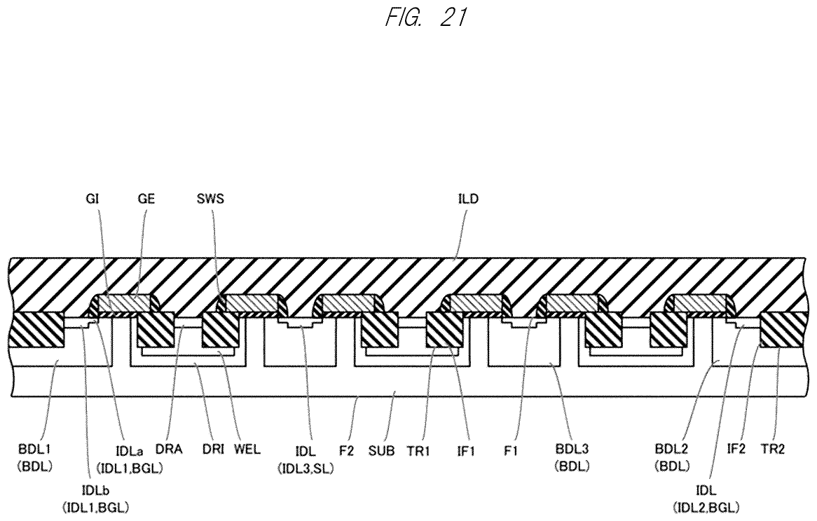

As illustrated in FIG. 19, in the ion implanting step S8, ion implantation is performed by using the resist pattern formed on the gate electrode GE, the sidewall spacer SWS, the insulating film IF1, and the upper surface F1 as a mask, thereby forming the second part IDLb (the source layer SL) of the impurity diffusion layer IDL3 and forming the drain layer DRA. As illustrated in FIG. 20, in the ion implanting step S9, ion implantation is performed by using the resist pattern formed on the gate electrode GE, the sidewall spacer SWS, the insulating film IF1, the insulating film IF2, and the upper surface F1 as a mask, thereby forming the second part IDLb (the backgate layer BGL) of the impurity diffusion layer IDL1 and the impurity diffusion layer IDL2. At this time, the second part IDLb (the backgate layer BGL) of the impurity diffusion layer IDL3 is also formed.

As illustrated in FIG. 21, in the interlayer-insulating-film forming step S10, the interlayer insulating film ILD is formed on the upper surface F1 to cover the insulating film IF1, the insulating film IF2, the sidewall spacer SWS, and the gate electrode GE. In the interlayer-insulating-film forming step S10, firstly, a constituent material of the interlayer insulating film ILD is deposited on the upper surface F1 to cover the insulating film IF1, the insulating film IF2, the sidewall spacer SWS, and the gate electrode GE. Secondly, an upper surface of the constituent material of the interlayer insulating film ILD is flattened by, for example, a CMP method.

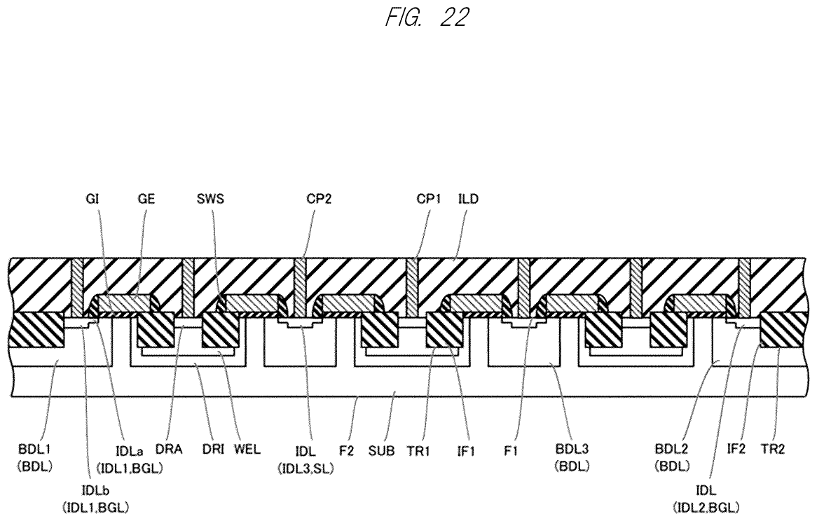

As illustrated in FIG. 22, in the contact-plug forming step S11, the contact plug CP1 and the contact plug CP2 are formed in the interlayer insulating film ILD. In the contact-plug forming step S11, firstly, the interlayer insulating film ILD is dry-etched through the openings of the resist pattern formed on the interlayer insulating film ILD, thereby forming the contact hole in the interlayer insulating film ILD. Secondly, a constituent material of the contact plug CP1 or the like is deposited in the contact hole and on the interlayer insulating film ILD by, for example, a CVD method. Thirdly, a constituent material of the contact plug CP1 or the like formed outside the contact hole is removed by, for example, a CMP method.

In the wiring forming step S12, the wiring WL1 and the wiring WL2 are formed on the interlayer insulating film ILD. In the wiring forming step S12, firstly, a constituent material of the wiring WL1 or the like is deposited on the interlayer insulating film ILD by, for example, sputtering. Secondly, the constituent material of the wirings WL1 or the like is dry-etched through the openings of the resist pattern formed on the constituent material of the wirings WL1 or the like. The structure of the semiconductor device DEV1 illustrated in FIGS. 1 to 9 is formed as described above.

### EFFECTS OF SEMICONDUCTOR DEVICE DEV1

In the LDMOS transistor Tr3, each of the impurity diffusion layer IDL1 and the impurity diffusion layer IDL2 includes not only the backgate layer BGL but also the source layer SL, and thus, the gate width of the LDMOS transistor Tr3 is larger than the gate width of each of the LDMOS transistor Tr1 and the LDMOS transistor Tr2. Consequently, the current capability of the LDMOS transistor Tr3 is higher than the current capability of each of the LDMOS transistor Tr1 and the LDMOS transistor Tr2.

However, in the formation of the insulating film IF1, the insulating films IF1 positioned on both ends in the second direction DR2 are influenced by the insulating film IF2, as different from the insulating films IF1 positioned on other region than both ends in the second direction DR2, and thus, the shapes of the insulating films IF1 positioned on both ends in the second direction DR2 are different from those of the insulating films IF1 positioned on other region than both ends in the second direction DR2. This also applies to the body layer BDL, the drift layer DRI, and the gate electrode GE positioned on both ends in the second direction DR2.

Consequently, in the LDMOS transistor Tr3, the electric properties such as threshold voltage, on-resistance, and saturation drain current in the channel between the source layer SL of the impurity diffusion layer IDL1 (the impurity diffusion layer IDL2) and the drain layer DRA are different from the electric properties in the channel between the source layer SL of the impurity diffusion layer IDL3 and the drain layer DRA. That is, the electric properties of the LDMOS transistor Tr3 are difficult to linearly change relative to the number of fingers. Thus, when the LDMOS transistor Tr3 is used for the current mirror circuit, even if the numbers of fingers among the transistors is adjusted in order to achieve a desired current ratio, the actual current ratio deviates from the desired current ratio, and accuracy in the current mirror circuit decreases.

To the contrary, in the LDMOS transistor Tr1 and the LDMOS transistor Tr2, the impurity diffusion layer IDL1 (the impurity diffusion layer IDL2) does not include the source layer SL, and thus, a region between the impurity diffusion layer IDL1 (the impurity diffusion layer IDL2) and the drain layer DRA is not used as the channel. Thus, a degree of the linear change of the electric properties of the LDMOS transistor Tr1 and the LDMOS transistor Tr2 relative to the number of fingers is more than that of the electric properties of the LDMOS transistor Tr3. Therefore, according to the semiconductor device DEV1, the accuracy in the analog circuit such as the current mirror circuit can be enhanced.

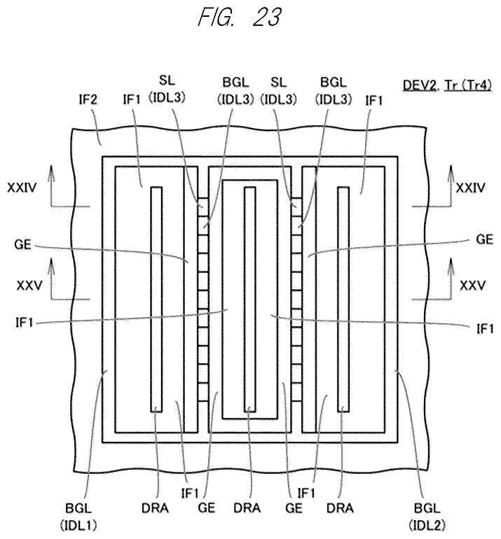

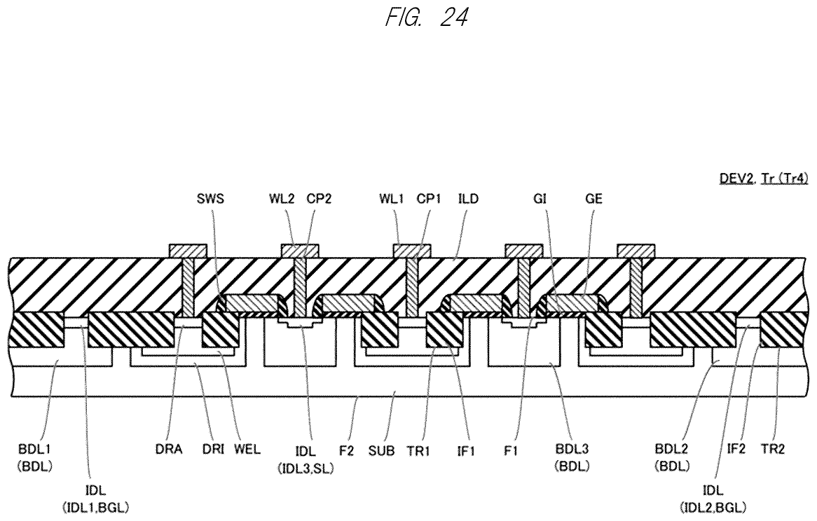

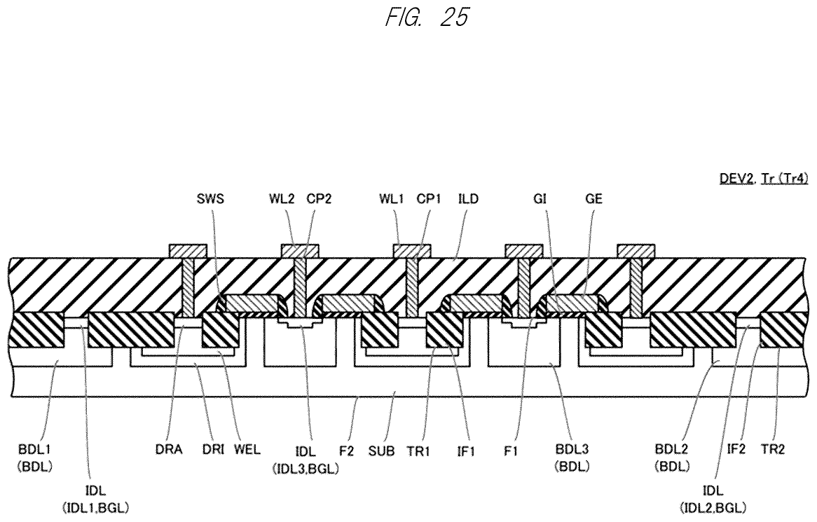

As illustrated in FIGS. 23 to 25, a semiconductor device DEV4 according to a comparative example includes an LDMOS transistor Tr4 as the LDMOS transistor Tr. In the LDMOS transistor Tr4, each of the impurity diffusion layer IDL1 and the impurity diffusion layer IDL2 includes only the backgate layer BGL. In the LDMOS transistor Tr4, the insulating films IF1 positioned on both ends in the second direction DR2 are in contact with both the impurity diffusion layer IDL1 (the impurity diffusion layer IDL2) and the drain layer DRA. In the LDMOS transistor Tr4, the gate electrode GE is not formed on the insulating films IF1 positioned on both ends in the second direction DR2.

In the LDMOS transistor Tr4, the impurity diffusion layer IDL1 (the impurity diffusion layer IDL2) does not include the source layer SL as similar to the LDMOS transistor Tr1 and the LDMOS transistor Tr2, and thus, a region between the impurity diffusion layer IDL1 (the impurity diffusion layer IDL2) and the drain layer DRA is not used as the channel. Thus, a degree of the linear change of the electric properties of the LDMOS transistor Tr4 relative to the number of fingers is more than that of the electric properties of the LDMOS transistor Tr3.

However, in the LDMOS transistor Tr4, the gate electrode GE is not formed on the insulating films IF1 positioned on both ends in the second direction DR2, and thus, the dielectric breakdown voltage is lower than those of the LDMOS transistor Tr1 and the LDMOS transistor Tr2 due to a difference in field plate effect. In another aspect, it is necessary to make the distance between the impurity diffusion layer IDL1 (the impurity diffusion layer IDL2) and the drain layer DRA larger than those of the LDMOS transistor Tr1 and the LDMOS transistor Tr2 in order to achieve the same dielectric breakdown voltage as those if the LDMOS transistor Tr1 and the LDMOS transistor Tr2. As described above, according to the semiconductor device DEV1, the plane dimensions of the LDMOS transistor Tr1 and the LDMOS transistor Tr2 can be reduced.

As described above, the LDMOS transistor Tr3 is difficult to apply to an analog circuit requiring high accuracy. However, when the analog circuit not requiring high accuracy but requiring high current capability is mounted on the semiconductor device DEV1, the LDMOS transistor Tr3 is applicable to such an analog circuit requiring high current capability.

In the LDMOS transistor Tr3, the smaller the number of fingers is, in other words, the smaller the number of the plurality of drain layers DRA is, the larger the influence of the electric properties on the channel between the source layer SL of the impurity diffusion layer IDL1 (the impurity diffusion layer IDL2) and the drain layer DRA is. Thus, the LDMOS transistor Tr1 and the LDMOS transistor Tr2 are particularly effective when the number of fingers is equal to or smaller than 10, in other words, when the number of the plurality of drain layers DRA is equal to or smaller than 6.

### Second Embodiment

A semiconductor device DEV2 according to a second embodiment will be described. The differences from the semiconductor device DEV1 will be mainly described herein, and the overlapping description will not be repeated.

### Configuration of Semiconductor Device DEV2

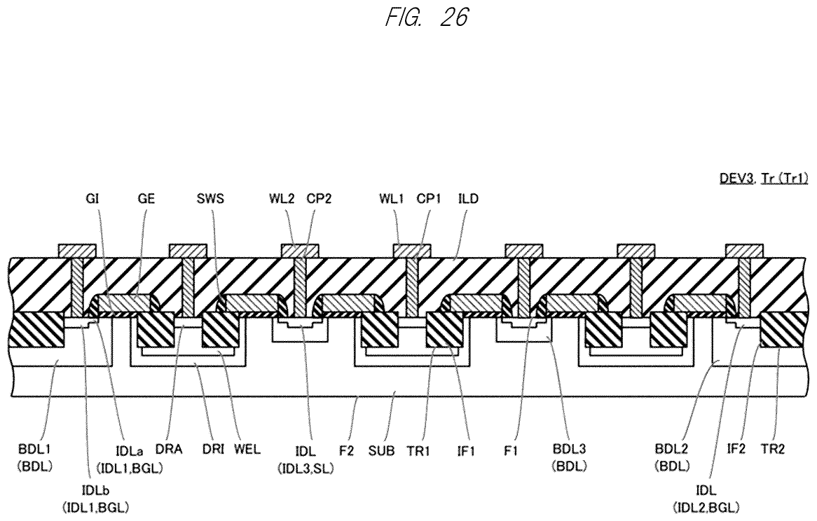

As illustrated in FIG. 26 the semiconductor device DEV2 includes an LDMOS transistor Tr1 as one of the plurality of LDMOS transistors Tr. In the LDMOS transistor Tr1 of the semiconductor device DEV2, the depth of the body layer BDL1 surrounding the impurity diffusion layer IDL1 in cross-sectional view and the depth of the body layer BDL2 surrounding the impurity diffusion layer IDL2 in cross-sectional view are larger than the depth of the body layer BDL3 surrounding the impurity diffusion layer IDL3 in cross-sectional view among the plurality of body layers BDL. The depth of the body layer BDL3 is smaller than the depth of the drift layer DRI. The depth of the body layer BDL (the drift layer DRI) corresponds to the distance between the lower surface of the body layer BDL (the drift layer DRI) and the upper surface F1.

In plan view in the LDMOS transistor Tr1 of the semiconductor device DEV2, the overlapping width of the gate electrode GE and the body layer BDL3 in the second direction DR2 is smaller than the overlapping width of the gate electrode GE and the body layer BDL1 in the second direction DR2 and the overlapping width of the gate electrode GE and the body layer BDL2 in the second direction DR2.

### Method of Manufacturing Semiconductor Device DEV2

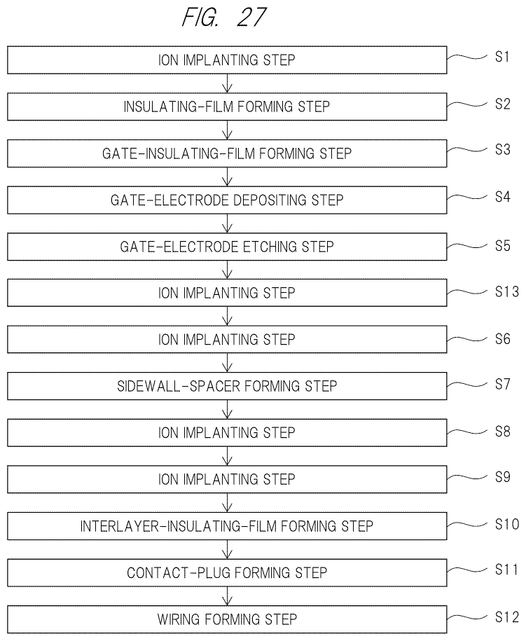

As illustrated in FIG. 27, a method of manufacturing the semiconductor device DEV2 further includes an ion implanting step S13.

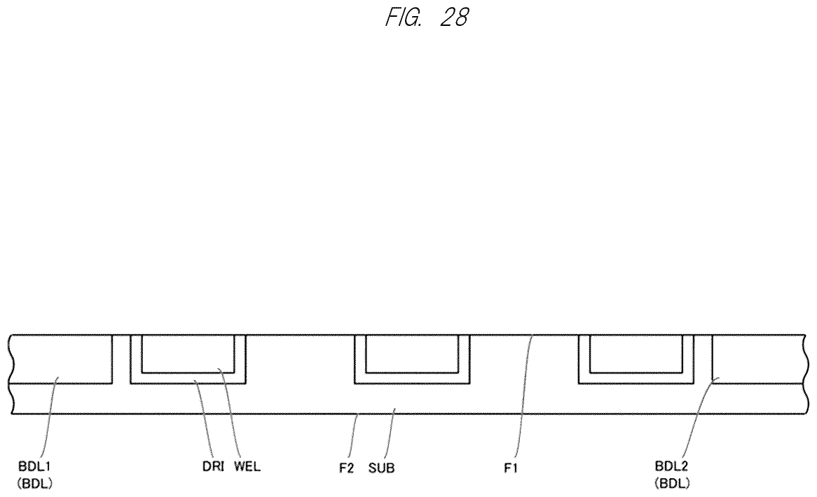

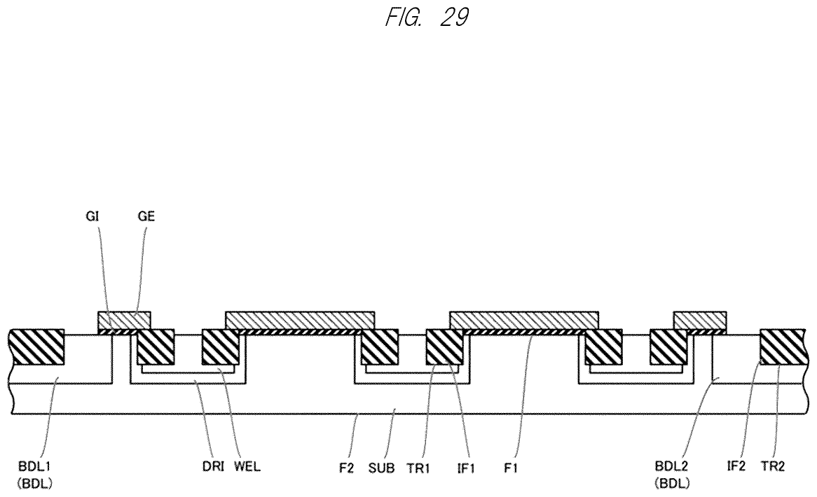

As illustrated in FIG. 28, in the method of manufacturing the semiconductor device DEV2, the body layer BDL3 is not formed by the ion implanting step S1. As illustrated in FIG. 29, in the method of manufacturing the semiconductor device DEV2, the gate electrode GE which is positioned above the formation portion of the body layer BDL3 is not removed by the gate-electrode etching step S5.

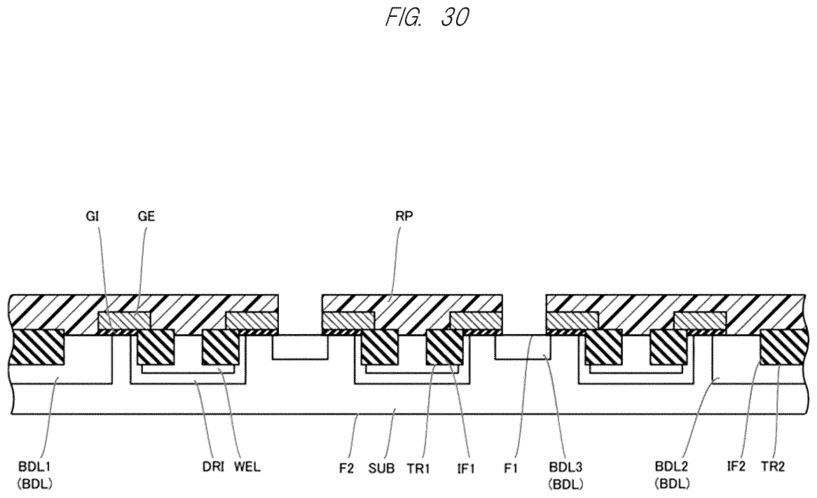

As illustrated in FIG. 30, the body layer BDL3 is formed in a self-aligned manner by ion implantation of the ion implanting step S13. In the ion implanting step S13, firstly, the resist pattern RP is formed on the upper surface F1 to cover the gate electrode GE, the insulating film IF1, and the insulating film IF2. The resist pattern RP has an opening above the formation portion of the body layer BDL3. Secondly, the gate electrode GE and the gate insulating film GI are dry-etched through the opening of the resist pattern RP to remove the gate electrode GE and the gate insulating film GI exposed from the opening of the resist pattern RP. Thirdly, the ion implantation is performed through the opening of the resist pattern RP. At this time, an ion implantation direction tilts from a normal-line direction of the upper surface F1.

Consequently, in plan view, the overlapping width of the gate electrode GE and the body layer BDL3 in the second direction DR2 is smaller than the overlapping width of the gate electrode GE and the body layer BDL1 in the second direction DR2 and the overlapping width of the gate electrode GE and the body layer BDL2 in the second direction DR2. The depth of the body layer BDL3 is also smaller than the depth of the body layer BDL1 and the depth of the body layer BDL2. After the ion implanting step S13, the steps from the ion implanting step S6 to the wiring forming step S12 are sequentially performed to form the structure of the semiconductor device DEV2 illustrated in FIG. 26.

### Effects of Semiconductor Device DEV2

In the LDMOS transistor Tr1 of the semiconductor device DEV2, the overlapping width of the gate electrode GE and the body layer BDL3 is smaller than the overlapping width of the gate electrode GE and the body layer BDL1 in the second direction DR2 and the overlapping width of the gate electrode GE and the body layer BDL2 in the second direction DR2, and thus, the channel length therein is smaller than that in the LDMOS transistor Tr1 of the semiconductor device DEV1. Thus, in the semiconductor device DEV2, the electric property (on-resistance) of the LDMOS transistor Tr1 is smaller.

### Third Embodiment

A semiconductor device DEV3 according to a third embodiment will be described. The differences from the semiconductor device DEV2 will be mainly described herein, and the overlapping description thereof will not be repeated.

### Semiconductor Device DEV3

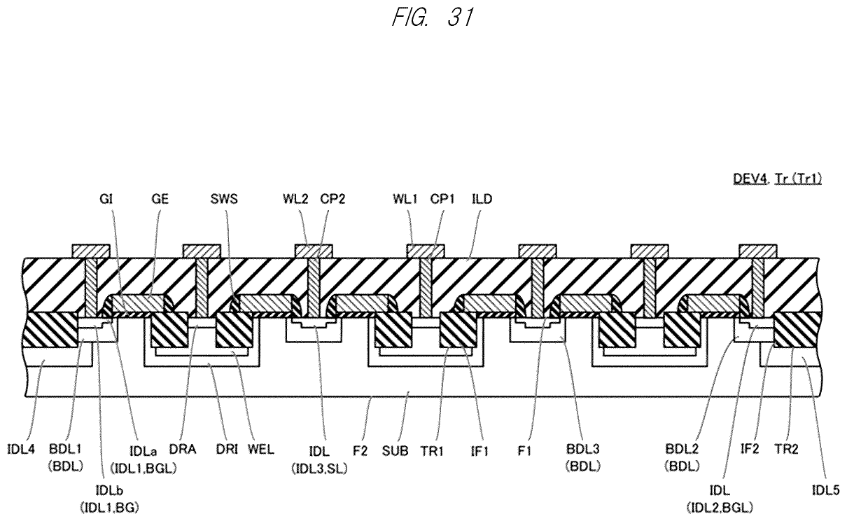

As illustrated in FIG. 31, the semiconductor device DEV3 includes an LDMOS transistor Tr1 as one of the plurality of LDMOS transistors Tr. In the LDMOS transistor Tr1 of the semiconductor device DEV3, the depth of each of the body layer BDL1 and the body layer BDL2 is almost equal to the depth of the body layer BDL3, and is smaller than the depth of the drift layer DRI. In the LDMOS transistor Tr1 of the semiconductor device DEV3, the overlapping width of the body layer BDL1 and the gate electrode GE in the second direction DR2 and the overlapping width of the body layer BDL2 and the gate electrode GE in the second direction DR2 are almost equal to the overlapping width of the body layer BDL3 and the gate electrode GE in the second direction DR2.

In the semiconductor device DEV3, the semiconductor substrate SUB may further include an impurity diffusion layer IDL4 and an impurity diffusion layer IDL5. The impurity diffusion layer IDL4 is formed below the body layer BDL1 in the semiconductor substrate SUB, and is in contact with the body layer BDL1. The impurity diffusion layer IDL5 is formed below the body layer BDL2 in the semiconductor substrate SUB, and is in contact with the body layer BDL2. Each conductive type of the impurity diffusion layer IDL4 and the impurity diffusion layer IDL5 is the first conductive type.

### Method of Manufacturing Semiconductor Device DEV3

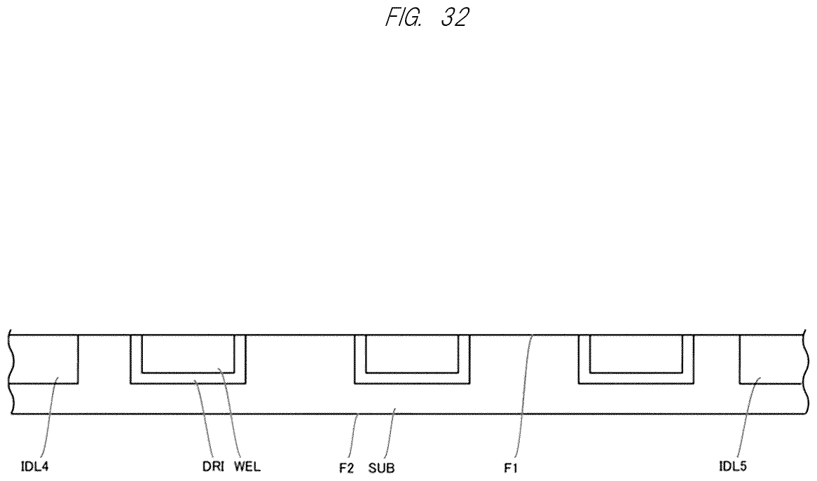

As illustrated in FIG. 32, in a method of manufacturing the semiconductor device DEV3, the impurity diffusion layer IDL4 and the impurity diffusion layer IDL5 are formed together with the well layer WEL and the drift layer DRI by ion implantation of the ion implanting step S1.

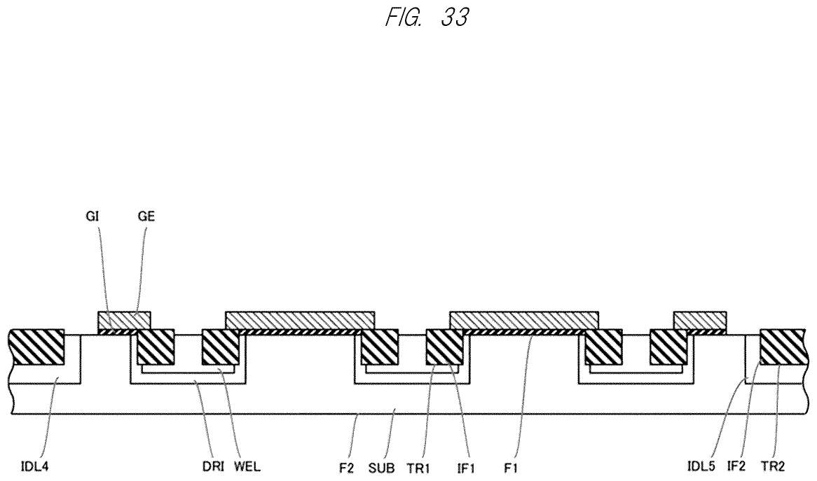

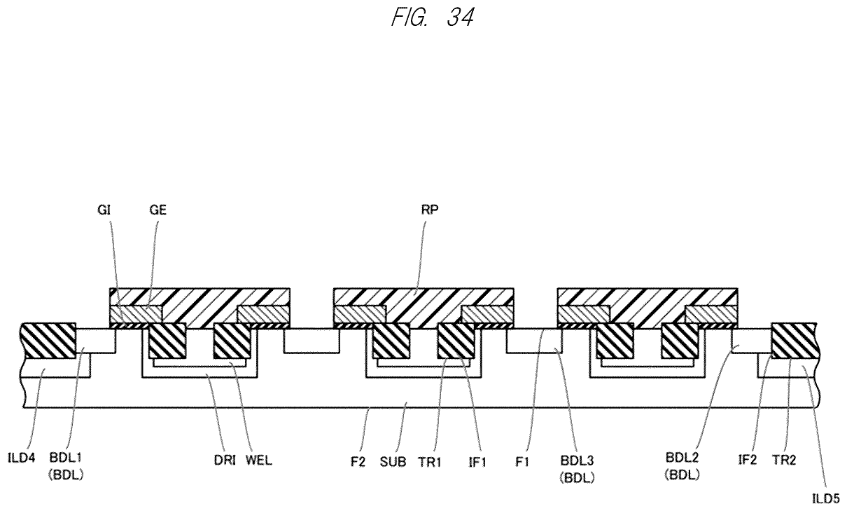

As illustrated in FIGS. 33 and 34, in the method of manufacturing the semiconductor device DEV3, the body layer BDL1 and the body layer BDL2 are formed in a self-aligned manner as similar to the body layer BDL3. More specifically, as illustrated in FIG. 33, the gate electrodes GE which are positioned above the formation regions of the body layer BDL1, the body layer BDL2, and the body layer BDL3 are not etched and remain in the gate-electrode etching step S5. As illustrated in FIG. 34, in the ion implanting step S13, the gate electrode GE and the gate insulating film GI are dry-etched through the openings of the resist pattern RP positioned above the formation regions of the body layer BDL1, the body layer BDL2, and the body layer BDL3, and then, the ion implantation is performed through the openings in the tilt direction from the normal-line direction of the upper surface F1.

### Effects of Semiconductor Device DEV3

In the semiconductor device DEV3, the same gate-electrode etching step S5 and ion implanting step S13 are applied to both ends of the LDMOS transistor Tr1 in the second direction DR2 and other region than the both ends of the LDMOS transistor Tr1 in the second direction DR2. Thus, in the LDMOS transistor Tr1 of the semiconductor device DEV3, even if the number of fingers is smaller, the gate electrode GE and the body layer BDL3 in the other region than the both ends in the second direction DR2 can be more appropriately formed than those in the LDMOS transistor Tr1 of the semiconductor device DEV2, and the electric properties of the LDMOS transistor Tr1 more linearly change relative to the number of fingers.

In the foregoing, the invention made by the inventors of the present application has been concretely described based on the embodiments. However, it is needless to say that the present invention is not limited to the foregoing embodiments, and various modifications can be made within the scope of the present invention.

What is claimed is:

1. A semiconductor device comprising:
one or more LDMOS transistors; and
a semiconductor substrate having an upper surface,
wherein each of the one or more LDMOS transistors includes:
a plurality of impurity diffusion layers formed in the semiconductor substrate at the upper surface;
a plurality of drain layers formed in the semiconductor substrate at the upper surface; and
a plurality of insulating films formed on the upper surface,
wherein each of the plurality of impurity diffusion layers, each of the plurality of drain layers, and each of the plurality of insulating films extend along a first direction in plan view,
wherein the plurality of impurity diffusion layers are arranged along a second direction perpendicular to the first direction in plan view while interposing a gap between two adjacent impurity diffusion layers among the plurality of impurity diffusion layers,
wherein the plurality of impurity diffusion layers include a first impurity diffusion layer and a second impurity diffusion layer which are positioned on both ends in the second direction, and a third impurity diffusion layer positioned between the first impurity diffusion layer and the second impurity diffusion layer,
wherein each of the plurality of drain layers is positioned between two adjacent impurity diffusion layers among the plurality of impurity diffusion layers,
wherein each of the plurality of insulating films is positioned between one of the plurality of drain layers and one of the plurality of impurity diffusion layers which are adjacent to each other, to be in contact with one of the plurality of drain layers and to separate from one of the plurality of impurity diffusion layers,
wherein each of the first impurity diffusion layer and the second impurity diffusion layer in a first LDMOS transistor among the one or more LDMOS transistors includes a first backgate layer but does not include a source layer, and
wherein the third impurity diffusion layer in the first LDMOS transistor includes a second backgate layer and a first source layer which are alternately arranged along the first direction.

2. The semiconductor device according to claim 1,
wherein each of the one or more LDMOS transistors further includes a plurality of gate insulating films and a plurality of gate electrodes,
wherein in the first LDMOS transistor, each of the plurality of gate insulating films is formed on the upper surface positioned between one of the plurality of impurity diffusion layers and one of the plurality of insulating films which are adjacent to each other, and
wherein in the first LDMOS transistor, each of the plurality of gate electrodes is formed on one of the plurality of gate insulating films and one of the plurality of insulating films which are adjacent to each other.

3. The semiconductor device according to claim 1,
wherein each of the one or more LDMOS transistors further includes a plurality of drift layers formed in the semiconductor substrate and a plurality of body layers formed in the semiconductor substrate,
wherein each of the plurality of drift layers is formed on the upper surface to surround each of the plurality of drain layers in cross-sectional view, and
wherein each of the plurality of body layers is formed on the upper surface to surround each of the plurality of impurity diffusion layers in cross-sectional view.

4. The semiconductor device according to claim 3,
wherein in the first LDMOS transistor, a depth of a first body layer surrounding the first impurity diffusion layer among the plurality of body layers and a depth of a second body layer surrounding the second impurity diffusion layer among the plurality of body layers are smaller than a depth of a third body layer surrounding the third impurity diffusion layer among the plurality of body layers.

5. The semiconductor device according to claim 3,
wherein in the first LDMOS transistor, a depth of each of the plurality of drift layers is larger than a depth of a first body layer surrounding the first impurity diffusion layer among the plurality of body layers, a depth of a second body layer surrounding the second impurity diffusion layer among the plurality of body layers, and a depth of a third body layer surrounding the third impurity diffusion layer among the plurality of body layers.

6. The semiconductor device according to claim 1,
wherein in the first LDMOS transistor, the number of the plurality of drain layers is equal to or smaller than six.

7. The semiconductor device according to claim 1,
wherein the one or more LDMOS transistors includes a plurality of LDMOS transistors,
wherein in a second LDMOS transistor among the plurality of LDMOS transistors, each of the first impurity diffusion layer and the second impurity diffusion layer includes a third backgate layer but does not include a source layer,
wherein in the second LDMOS transistor, the third impurity diffusion layer includes a fourth backgate layer and a second source layer which are alternately arranged along the first direction,
wherein the number of the plurality of drain layers in the first LDMOS transistor is different from the number of the plurality of drain layers in the second LDMOS transistor, and
wherein the first LDMOS transistor and the second LDMOS transistor configure a current mirror circuit.

8. The semiconductor device according to claim 1,
wherein the one or more LDMOS transistors includes a plurality of LDMOS transistors, and
wherein in a third LDMOS transistor among the plurality of LDMOS transistors, each of the first impurity diffusion layer, the second impurity diffusion layer, and the third impurity diffusion layer includes a fifth backgate layer and a third source layer which are alternately arranged along the first direction.

9. The semiconductor device according to claim 1,
wherein a length of the first backgate layer in the first direction is larger than a length of the second backgate layer in the first direction.
